(19) United States
(12) Patent Application Publication
(10) Pub. No.: US 2009/0134385 A1
(43) Pub. Date: May 28, 2009

(54) Organic Line Detector and Method for the Production Thereof

(75) Inventor: Christoph Brabec, Linz (AT)

Correspondence Address: YOUNG & THOMPSON, 209 Madison Street, Suite 500, ALEXANDRIA, VA, 22314, US

(73) Assignee: Siemens Aktiengesellschaft, Munchen (DE)

(21) Appl. No.: 11/922,350

(22) PCT Filed: Jun. 12, 2006
(86) PCT No.: PCT/EP2006/063097

§ 371 Date: Jul. 22, 2008

(30) Foreign Application Priority Data
Jun. 16, 2005 (DE) 10 2005 027 902.3

(51) Int. Cl. H01L 51/48; H01L 51/44

(52) U.S. Cl. 257/40; 438/82; 257/E21.158; 257/E51.012; 257/448

(57) ABSTRACT

A method for producing an organic line detector for applications in the field of computer tomography, includes the following steps: selective etching is carried out on an indium-tin-oxide (ITO) applied to a substrate; two separate ITO strips are formed by the etching; at least one structured mushroom photosensitive resist is applied between the ITO strips; at least one organic perforated conductor is applied to the mushroom photosensitive resist and the ITO strips, only adhering to the ITO strips; at least one organic semiconductor is applied to the layer of the organic perforated conductor, only adhering to the organic perforated conductor and not to the mushroom photosensitive resist; and at least two negative cup-type electrodes are applied to the organic semiconductor, the cup-type electrodes being separate from each other.

The present invention relates to an organic line detector and a method for producing an organic line detector for computed tomography.

Line detectors are nowadays preferably used for medical and technical applications of computed tomography (CT), and in particular for two-dimensional computed tomography (2D-CT).

In 2D-CT, the object under examination is irradiated by a fan beam of an X-ray source and the transmitted intensity is measured with a line detector.

During rotation of the object, a two-dimensional section is reconstructed in the measuring plane from several hundred one-dimensional projections. A three-dimensional result is obtained by displacing the object in the axial direction for each measurement until a sufficient number of sections is available.

This principle is used both in medical and industrial CT equipment.

The advantages of the line detectors are their high efficiency and the fact that scattered radiation is largely suppressed.

Common line detectors are nowadays direct converters, such as xenon gas detectors or solid state scintillation converters which are based on a scintillating material such as cadmium tungstate (CdWO₄) or rare earth elements.

Corresponding line detectors which incorporate organic hole conductors and semiconductors and are easy to apply in process engineering terms, are as yet unknown.

The object of the present invention is therefore to provide a method for producing an organic line detector which incorporates hole conductors and semiconductors with correspondingly separate line geometry.

As organic hole conductors and semiconductors are not amenable to etching processes, electrical isolation of the individual lines of the line detector is achieved by means of so-called mushroom photoresist patterns.

To achieve the stated object, the present invention teaches a method for producing an organic line detector comprising the following steps:

selectively etching an indium-tin-oxide (ITO) layer disposed on a substrate, said ITO layer and substrate constituting a positive semi-transparent electrode, and at least two ITO tracks which are separated from one another being formed by said etching,
applying at least one patterned mushroom photoresist between the ITO tracks,
applying at least one organic hole conductor to the mushroom photoresist and ITO tracks, the at least one organic hole conductor adhering only to the ITO tracks,
applying at least one organic semiconductor to the organic hole conductor layer, the organic semiconductor adhering only to the organic hole conductor and not to the mushroom photoresist,
applying at least two negative top electrodes to the organic semiconductor, said top electrodes being separated from one another.

The advantage of the present invention's inventive method for producing an organic line detector is that the top electrodes are electrically isolated from one another, thereby providing semiconductor separation.

According to another aspect of the present invention of a method for producing an organic line detector, it is preferred that the line detector comprises 16 mutually separated ITO tracks, and therefore 16 mutually separated organic hole conductor tracks, 16 mutually separated organic semiconductor tracks and 16 mutually separated top electronic tracks in order to provide a line detector with 16 lines. The advantage of this is that the individual 16 lines of the line detector are electrically isolated from one another and no short circuits occur. In addition, 16-line detectors are required primarily for CT applications.

According to another aspect of the present invention of a method for producing an organic line detector, it is preferred that the distances between the lines of the organic line detector are identical. The advantage of this is that the line detector provides high image quality and can also be produced simply and inexpensively.

According to another aspect of the present invention of a method for producing an organic line detector, it is preferred that the distances between the lines of the organic line detector are different. The advantage of this is that the line detector can be adapted to suit the particular application.

According to another aspect of the present invention of a method for producing an organic line detector, it is preferred that the substrate contains glass and/or a plastic film. The advantage of this is that the electrode is semi-transparent and permeable to low energy radiation.

Another advantage of using a plastic film is that it is lightweight and readily processable. Glass or plastic film substrates are likewise inexpensive to produce.

According to another aspect of the present invention of a method for producing an organic line detector, it is preferred that the plastic film is flexible. The advantage of this is that the film can be applied to non-planar surfaces.

According to another aspect of the present invention of a method for producing an organic line detector, it is preferred that the plastic film is a polymer film. The advantage of this is that the film can be applied to non-planar surfaces and is also inexpensive to produce.

According to another aspect of the present invention of a method for producing an organic line detector, it is preferred that the organic hole conductor contains PEDOT. This has the advantage of providing optimum charge transfer from the semi-transparent positive electrode to the negative top electrode.

According to another aspect of the present invention of a method for producing an organic line detector, it is preferred that the organic semiconductor contains P3HT and/or PCBM. This has the advantage of providing optimum charge transfer from the semi-transparent positive electrode to the negative top electrode.

According to another aspect of the present invention of a method for producing an organic line detector, it is preferred that the top electrode contains a metal. This has the advantage in the present invention of providing improved charge carrier transport between the positive semi-transparent electrode and the top electrode.

According to another aspect of the present invention of a method for producing an organic line detector, it is preferred that the top electrode contains Ca and/or Al and/or Au and/or Ag and/or Pt. This has the advantage in the present invention of providing improved charge carrier transport between the positive semi-transparent electrode and the top electrode, thereby likewise enabling better contacting of the electrode on the organic semiconductor to be achieved.

According to another aspect of the present invention of a method for producing an organic line detector, it is preferred that the mutually separated tracks are parallel. The advantage of this is that corresponding CT applications have improved resolution and the line detector can be simply produced.

According to another aspect of the present invention of a method for producing an organic line detector, it is preferred that the mutually separated tracks exhibit any desired geometry. The advantage of this is that the detector has an improved resolution in corresponding CT applications.

It is additionally preferred according to another aspect of the present invention that the at least one mushroom photoresist pattern is applied by means of spincasting. The advantage of this is that the mushroom photoresist patterns of the present invention can be applied simply, quickly and inexpensively between the ITO tracks.

It is additionally preferred according to a production method of an organic line detector of the present invention that the organic hole conductor 4 is applied by means of spincasting. The advantage of this is that the organic hole conductor of the present invention can be applied simply, quickly and inexpensively to the mushroom photoresist patterns and to the ITO tracks.

Another advantage of this is that the organic hole conductor layer tears off at the mushroom photoresist patterns and only adheres to the ITO tracks.

It is additionally preferred according to a production process of an organic line detector of the present invention that the organic semiconductor is applied by means of spincasting. The advantage of this is that the organic hole conductor of the present invention can be simply, quickly and inexpensively applied to the mushroom photoresist patterns and to the organic hole conductor.

Another advantage of this is that the organic semiconductor layer tears off at the mushroom photoresist patterns and only adheres to the ITO tracks.

This means that the individual lines comprising the semi-transparent electrodes, ITO track, organic hole conductor, organic semiconductor and a top electrode are electrically isolated from one another.

It is additionally preferred according to a production process of an organic line detector of the present invention that the mushroom photoresist patterns have negative edges of the kind known from OLED (organic light emitting diode) technology. The advantage of this is that the mushroom photoresist patterns can be simply applied between the ITO patterns and have a selective effect for the subsequent organic layer of a hole conductor, said hole conductor only adhering to the ITO patterns.

Another advantage of the negative edges of the mushroom photoresist patterns is that the mushroom photoresist patterns have a selective effect for the subsequent organic layer of a semiconductor, said semiconductor only adhering to the organic hole conductor.

It is additionally preferred according to a production process of an organic line detector of the present invention that the organic line detector is used for applications in the computed tomography field. The advantage of this is that, using organic hole conductors and semiconductors, the line detector of the present invention permits simpler and less expensive production of line detectors for CT applications and provides superior image quality compared to conventional line detectors.

The present invention also teaches an organic line detector comprising:

a substrate on which at least two indium-tin-oxide (ITO) tracks are disposed, said tracks being separated from one another and the ITO layer and substrate forming a positive semi-transparent electrode,
patterned mushroom photoresist deposited between the ITO tracks,
at least one organic hole conductor which is disposed only on the ITO tracks,
at least one organic semiconductor which is disposed only on the organic hole conductor,
at least two negative top electrodes which are disposed only on the organic semiconductor, said top electrodes being separated from one another.

According to another aspect of the present invention it is preferred that the organic line detector comprises 16 mutually separated ITO tracks, 16 mutually separated organic hole conductor tracks, 16 mutually separated organic semiconductor tracks and 16 mutually separated top electronic tracks which constitute the lines of the organic line detector. The advantage of this is that the line detector provides optimum image quality and is simple to produce.

According to another aspect of the present invention it is preferred that the distances between the lines of the organic line detector are identical. The advantage of this is that the line detector provides optimum image quality and is simple to produce.

According to another aspect of the present invention it is preferred that the distances between the lines of the organic line detector are different. The advantage of this is that the line detector provides optimum image quality and is simple to produce.

According to another aspect of the present invention it is preferred that the substrate contains glass and/or a plastic film. The advantage of this is that the line detector can be produced inexpensively.

According to another aspect of the present invention it is preferred that the plastic film is flexible. The advantage of this is that the line detector can be used in a customized manner.

According to another aspect of the present invention it is preferred that the plastic film is a polymer film. The advantage of this is that the line detector is inexpensive to produce.

According to another aspect of the present invention it is preferred that the organic hole conductor contains PEDOT. The advantage of this is that the line detector provides optimum image quality and is simple to produce.

According to another aspect of the present invention it is preferred that the organic semiconductor contains P3HT and/or PCBM. The advantage of this is that the line detector provides optimum image quality and is simple to produce.

According to another aspect of the present invention it is preferred that the top electrode contains a metal. The advantage of this is that the line detector provides optimum image quality and is simple to produce.

According to another aspect of the present invention it is preferred that the top electrode contains Ca and/or Al and/or Au and/or Ag and/or Pt. The advantage of this is that the line detector provides optimum image quality and is simple to produce. In addition, it provides improved contacting to the electrodes of the line detector.

According to another aspect of the present invention it is preferred that the mutually separated tracks are parallel. The advantage of this is that the line detector provides optimum image quality and is simple to produce.

According to another aspect of the present invention it is preferred that the mutually separated tracks exhibit any desired geometry. The advantage of this is that the line detector can be used in a customized manner.

According to another aspect of the present invention it is preferred that the mushroom photoresist patterns have negative edges. The advantage of this is that the line detector provides optimum image quality and is simple to produce.

Further advantages, features and possible applications of the present invention will emerge from the following description of preferred embodiments with reference to the accompanying drawings in which:

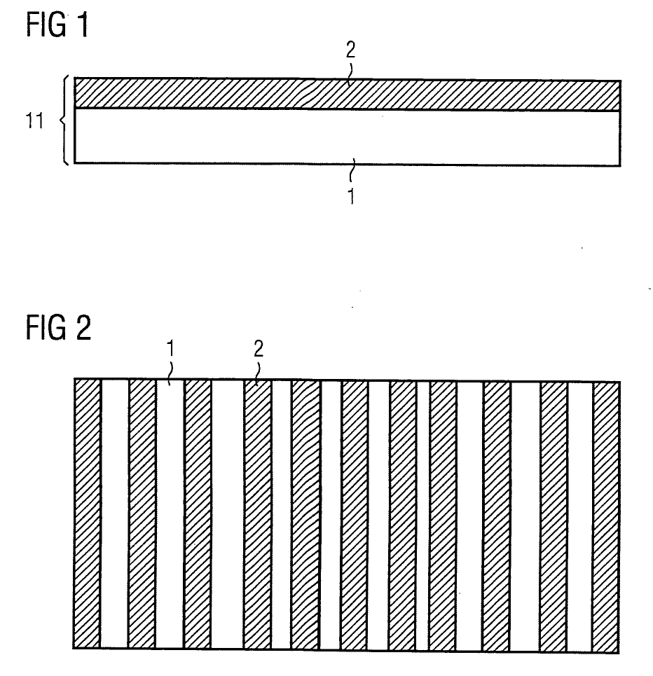

FIG. 1 shows a cross-sectional view of a substrate coated with indium-tin-oxide (ITO).

FIG. 2 shows a plan view of etched track patterns in the ITO layer.

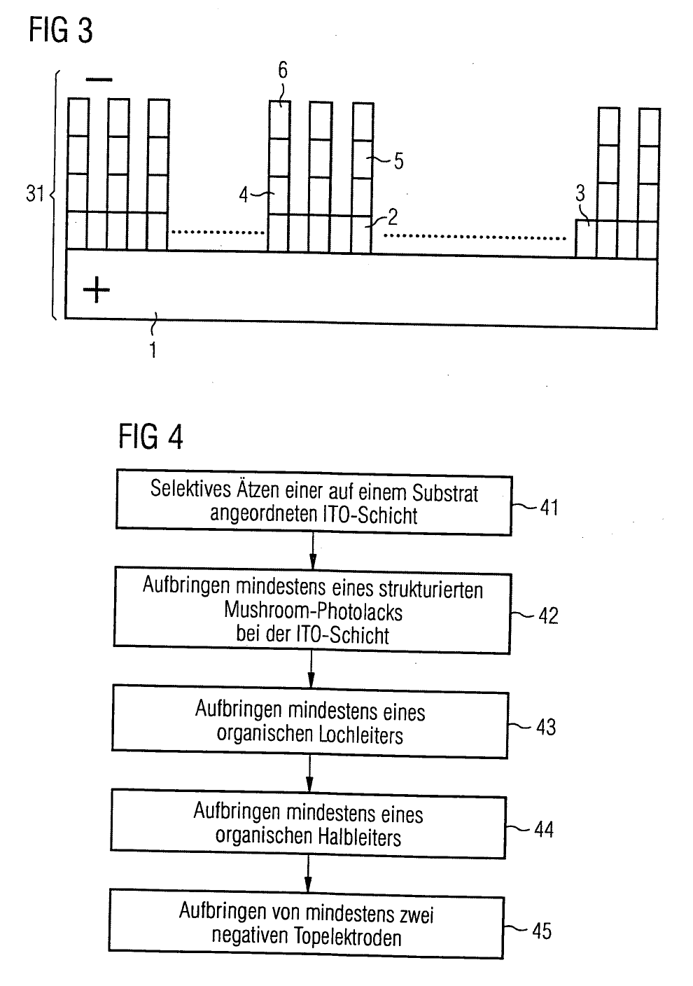

FIG. 3 shows a cross-sectional view of a preferred embodiment of the present invention with separate ITO tracks, organic hole conductor, organic semiconductor and separate top electrodes.

FIG. 4 shows a schematic flowchart of a method for producing an organic line detector of the present invention.

FIG. 1 shows a cross-sectional view of a substrate 1 coated with indium-tin-oxide (ITO) 2.

The ITO layer 2 is applied as a coating to the substrate 1 which can be comprised of glass or a flexible plastic film.

The substrate can likewise contain a polymer film.

The substrate 1 and the applied ITO layer 2 constitute a semi-transparent positive electrode 11 which is subsequently used as the front of the line detector.

FIG. 2 shows a plan view of etched track patterns in the ITO layer 2. This image is obtained after etching of the semi-transparent electrode 11.

The tracks 2 illustrated in this embodiment have a parallel, linear orientation with respect to one another and it should be noted that the tracks are separated from each other.

An embodiment is likewise conceivable wherein the tracks can have any desired geometry and can be disposed with any desired mutual separation.

FIG. 3 shows a cross-sectional view of a preferred embodiment of the present invention with separate ITO tracks 2, organic hole conductor 4, organic semiconductor 5 and separate top electrodes 6.

In a first step of the method, the homogeneous ITO layer 2 on the substrate 1 is patterned by means of an etching process and selectively etched.

According to a preferred embodiment, the linear ITO tracks 2 are parallel to one another and spaced the same distance apart.

Likewise conceivable, as already explained in connection with FIG. 2, is an embodiment where the ITO tracks 2 can assume any desired geometry and position on the substrate.

When etching is complete, so-called mushroom photoresist patterns 3 are applied between the ITO tracks 2, it being possible for a spincasting process to be used.

An organic hole conductor 3 is then spincast onto the ITO tracks 2 and the intervening mushroom photoresist patterns 3.

During spincasting of the organic hole conductor, the organic hole conductor patterns tear off at the mushroom patterns 3 so that the layers between the individual lines are separated.

The organic hole conductor adheres only to the surface of the ITO tracks 2 facing away from the substrate 1.

An organic semiconductor 5 is then spincast onto the existing line pattern comprising substrate 1, ITO 2, mushroom photoresist patterns 3 and organic hole conductor 4.

The same effect occurs as for the organic hole conductor, namely that the organic semiconductor 5 does not adhere to the mushroom photoresist patterns 3 but only to the organic hole conductor 5 and therefore to the ITO tracks 2.

When the organic semiconductor 5 has been spincast on, a top electrode 6 is finally spincast onto each of the lines which are likewise electrically separated from one another.

The mushroom photoresist patterns 3 therefore provide good electrical isolation of the top electrodes 6 between the lines of the line detector of the present invention.

When radiation is incident on the semi-transparent electrode 11, this produces a potential difference between the top electrode 6 and the semi-transparent electrode 11, charge transfer of electrodes between the top electrode 6 and the semi-transparent electrode 11 occurring in the direction of the semi-transparent electrode 11 on the one hand, and charge transfer of holes occurring in the direction of the top electrode 6 on the other.

FIG. 4 is a schematic flowchart of the method for producing an organic line detector of the present invention.

In the method for producing an organic line detector for computed tomography, in step 41 the substrate 1 on which a indium-tin-oxide (ITO) layer 2 is disposed is selectively etched, the ITO layer and the substrate forming a positive semi-transparent electrode 11.

The etching process produces at least two ITO tracks 2 which are separated from one another.

In step 42, at least one patterned mushroom photoresist 3 is applied between the ITO tracks 2.

Step 43 shows the application of at least one organic hole conductor 4 to the mushroom photoresist 3 and the ITO tracks 2, the at least one organic hole conductor 4 adhering only to the ITO tracks 2.

Step 44 shows the application of at least one organic semiconductor 5 to the layer of organic hole conductor 4, the organic semiconductor 5 adhering only to the organic hole conductor 4 and not to the mushroom photoresist 3.

Finally, step 45 shows the application of at least two negative top electrodes 6 to the organic semiconductor 5, said top electrodes 6 being separated from one another.

1. A method for producing an organic line detector for computed tomography, comprising the following steps:
selectively etching an indium-tin-oxide (ITO) layer (2) disposed on a substrate (1), the ITO layer and the substrate constituting a positive semi-transparent electrode (11) and wherein at least two mutually separated ITO tracks (2) are etch-formed,
applying at least one patterned mushroom photoresist (3) between the ITO tracks (2),
applying at least one organic hole conductor (4) to the mushroom photoresist (3) and the ITO tracks (2), the at least one organic hole conductor (4) adhering only to the ITO tracks (2),
applying at least one organic semiconductor (5) to the layer of organic hole conductor (4), the organic semiconductor (5) adhering only to the organic hole conductor (4) and not to the mushroom photoresist (3),
applying at least two negative top electrodes (6) to the organic semiconductor (5), said top electrodes (6) being separated from one another.

2. The method for producing an organic line detector as claimed in claim 1, wherein the line detector 16 comprises mutually separated ITO tracks (2), 16 mutually separated organic hole conductor tracks (4), 16 mutually separated organic semiconductor tracks (5) and 16 mutually separated top electrode tracks (6) which constituted the lines of the organic line detector.

3. The method for producing an organic line detector as claimed in claim 1, wherein the distances between the lines of the organic line detector are identical.

4. The method for producing an organic line detector as claimed in claim 1, wherein the distances between the lines of the organic line detector are different.

5. The method for producing an organic line detector as claimed in claim 1, wherein the substrate (1) contains glass and/or a plastic film.

6. The method for producing an organic line detector as claimed in claim 3, wherein the plastic film is flexible.

7. The method for producing an organic line detector as claimed in claim 3, wherein the plastic film is a polymer film.

8. The method for producing an organic line detector as claimed in claim 1, wherein the organic hole conductor contains PEDOT.

9. The method for producing an organic line detector as claimed in claim 1, wherein the organic semiconductor contains P3HT and/or PCBM.

10. The method for producing an organic line detector as claimed in claim 1, wherein the top electrode (6) contains a metal.

11. The method for producing an organic line detector as claimed in claim 1, wherein the top electrode (6) contains Ca and/or Al and/or Au and/or Ag and/or Pt.

12. The method for producing an organic line detector as claimed in claim 1, wherein the mutually separated tracks are parallel.

13. The method for producing an organic line detector as claimed in claim 1, wherein the mutually separated tracks have any desired geometry.

14. The method for producing an organic line detector as claimed in claim 1, wherein the mushroom photoresist patterns (3) are applied by means of spincasting.

15. The method for producing an organic line detector as claimed in claim 1, wherein the organic hole conductor (4) is applied by means of spincasting.

16. The method for producing an organic line detector as claimed in claim 1, wherein the organic semiconductor (5) is applied by means of spincasting.

17. The method for producing an organic line detector as claimed in claim 1, wherein the mushroom photoresist patterns (3) have negative edges.

18. The method for producing an organic line detector as claimed in claim 1, wherein the organic line detector is used for applications in the computed tomography field.

19. An organic line detector (31) for computed tomography, comprising:
a substrate (1) with at least two indium-tin-oxide (ITO) tracks (2) disposed thereon, said tracks being separated from one another, and the ITO layer and substrate forming a positive semi-transparent electrode (11),
a patterned mushroom photoresist (3) which located between the ITO tracks (2),
at least one organic hole conductor (4) which is disposed only on the ITO tracks (2),
at least one organic semiconductor (5) which is disposed only on the organic hole conductor (4),
at least two negative top electrodes (6) which are disposed only on the organic semiconductor (5), said top electrodes (6) being separated from one another.

20. The organic line detector (31) for computed tomography as claimed in claim 19, wherein the line detector comprises 16 mutually separated ITO tracks (2), 16 mutually separated organic hole conductor tracks (4), 16 mutually separated organic semiconductor tracks (5) and 16 mutually separated top electrode tracks (6) which constitute the lines of the organic line detector.

21. The organic line detector (31) for computed tomography as claimed in claim 19, wherein the distances between the lines of the organic line detector are identical.

22. The organic line detector (31) for computed tomography as claimed in claim 19, wherein the distances between the lines of the organic line detector are different.

23. The organic line detector (31) for computed tomography as claimed in claim 19, wherein the substrate (1) contains glass and/or a plastic film.

24. The organic line detector (31) for computed tomography as claimed in claim 23, wherein the plastic film is flexible.

25. The organic line detector (31) for computed tomography as claimed in claim 24, wherein the plastic film is a polymer film.

26. The organic line detector (31) for computed tomography as claimed in claim 19, wherein the organic hole conductor contains PEDOT.

27. The organic line detector (31) for computed tomography as claimed in claim 19, wherein the organic semiconductor contains P3HT and/or PCBM.

28. The organic line detector (31) for computed tomography as claimed in claim 19, wherein the top electrode (6) contains a metal.

29. The organic line detector (31) for computed tomography as claimed in claim 19, wherein the top electrode (6) contains Ca and/or Al and/or Au and/or Ag and/or Pt.

30. The organic line detector (31) for computed tomography as claimed in claim 19, wherein the mutually separated tracks are parallel.

31. The organic line detector (31) for computed tomography as claimed in claim 19, wherein the mutually separated tracks have any desired geometry.

32. The organic line detector (31) for computed tomography as claimed in claim 19, wherein the mushroom photoresist patterns (3) have negative edges.
